(19) United States
(12) Patent Application Publication
(10) Pub. No.: US 2026/0068277 A1
(43) Pub. Date: Mar. 5, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yun Ju FAN, Hsinchu (TW); Lo-Heng CHANG, Hsinchu (TW); Huan-Chieh SU, Changhua (TW); Chih-Hao WANG, Hsinchu (TW)

(21) Appl. No.: 18/986,936

(22) Filed: Dec. 19, 2024

Related U.S. Application Data
(60) Provisional application No. 63/689,930, filed on Sep. 3, 2024.

(51) Int. Cl. H10D 64/62; H10D 64/01

(52) U.S. Cl. CPC H10D 64/62; H10D 64/01

(57) ABSTRACT

A semiconductor device structure and methods of forming the same are described. The structure includes an interlayer dielectric (ILD) layer, a first semiconductor material disposed adjacent the ILD layer, a semiconductor layer disposed adjacent the first semiconductor material, a second semiconductor material disposed between the semiconductor layer and the first semiconductor material, and a third semiconductor material disposed over the first semiconductor material. The third semiconductor material wraps at least two sides of the first semiconductor material. The structure further includes a silicide layer disposed on the third semiconductor material and a conductive feature disposed on the silicide layer.

### CROSS-REFERENCE TO RELATED APPLICATIONS

This application claims priority to U.S. Provisional Application Ser. No. 63/689,930 filed Sep. 3, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6, 7, 8, 9, 10, 11, 12, 13, and 14 are cross-sectional side views of various stages of manufacturing the semiconductor device structure taken along line A-A of FIG. 5, in accordance with some embodiments.

FIGS. 15 and 16 are perspective views of various stages of manufacturing the semiconductor device structure, in accordance with some embodiments.

FIGS. 17A, 18A, 19A, 20A, 21A, and 22A are perspective views of various stages of manufacturing the semiconductor device structure, in accordance with some embodiments.

FIGS. 17B, 18B, 19B, 20B, 21B, and 22B are corresponding cross-sectional side views of the semiconductor device structure of FIGS. 17A, 18A, 19A, 20A, 21A, and 22A, respectively, in accordance with some embodiments.

FIG. 23 is a cross-sectional side view of one of various stages of manufacturing the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

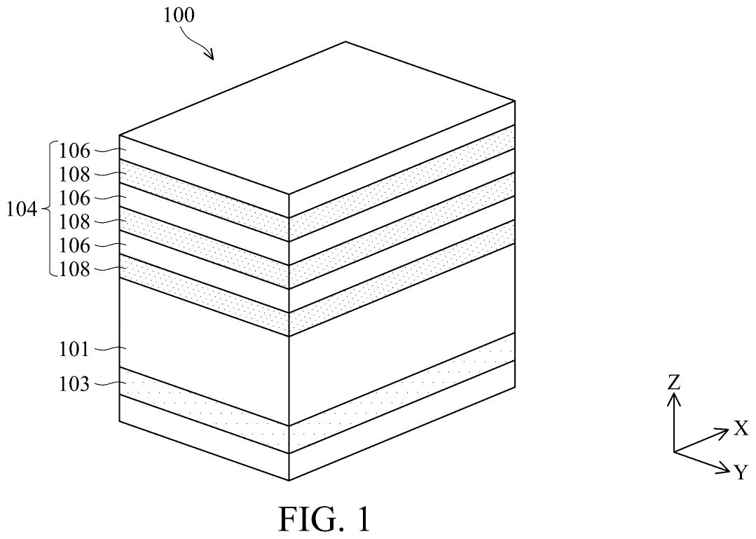

FIGS. 1-22B show exemplary processes for manufacturing a semiconductor device structure 100 according to embodiments of the present disclosure. It is understood that additional operations can be provided before, during, and after processes shown by FIGS. 1-22B, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

In some embodiments, as shown in FIG. 1, the substrate 101 includes a layer 103 made of a material different from the material of the substrate 101. In some embodiments, the substrate 101 is a silicon substrate, and the layer 103 is made of SiGe. The layer 103 may function as a stop layer during backside processes.

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

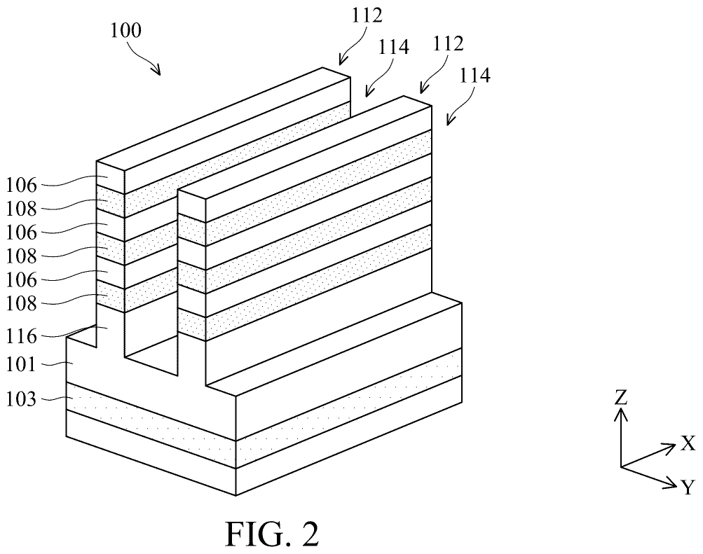

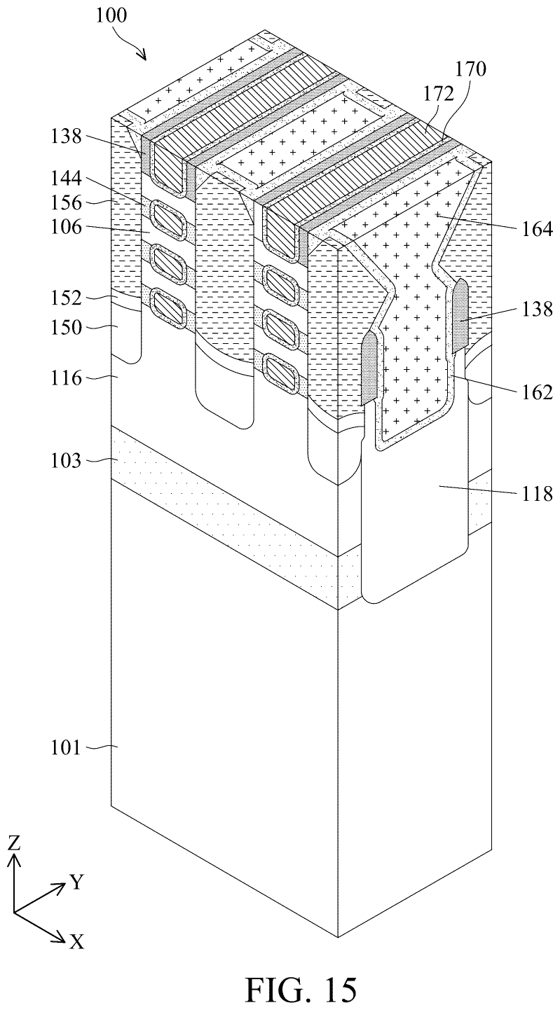

As shown in FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, the trenches 114 are located over the layer 103, as shown in FIG. 2. In some embodiments, the trenches 114 are also formed in the layer 103, as shown in FIG. 15.

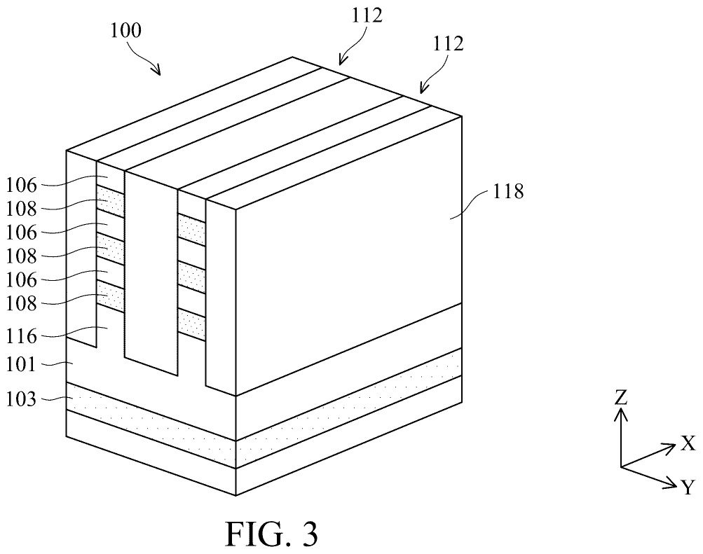

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

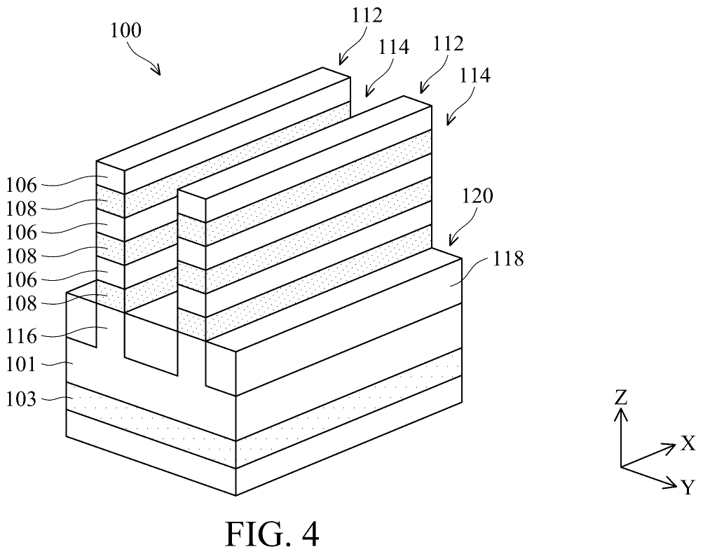

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions.

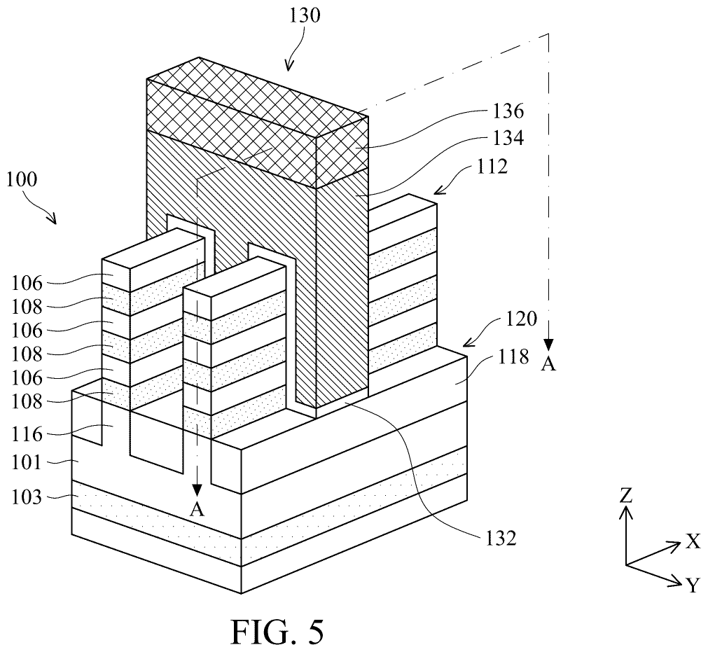

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

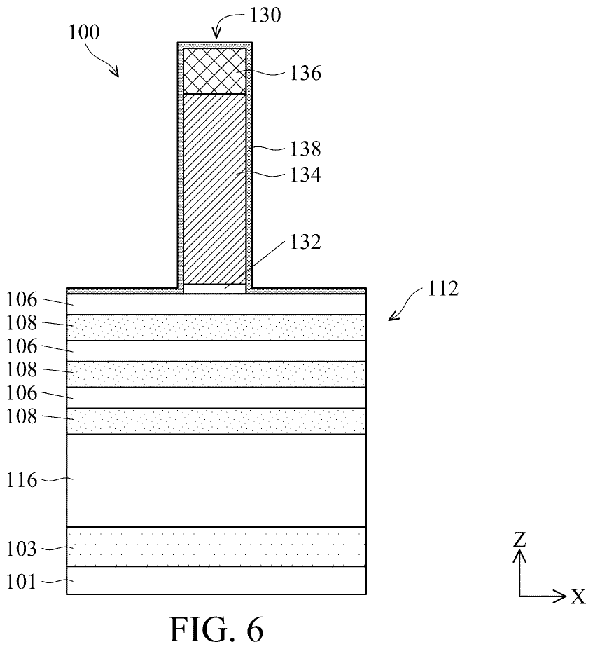

FIGS. 6-14 are cross-sectional side views of various stages of manufacturing the semiconductor device structure 100 taken along line A-A of FIG. 5, in accordance with some embodiments. As shown in FIG. 6, a first spacer 138 is deposited on the exposed surfaces of the semiconductor device structure 100. For example, the first spacer 138 is deposited on the fin structures 112, the isolation regions 120, and the sacrificial gate structure 130. The first spacer 138 may be made of a dielectric material such as silicon oxide, silicon nitride, silicon carbide, silicon oxynitride, SiCN, silicon oxycarbide, SiCON, and/or combinations thereof. The first spacer 138 may be formed by any suitable process. In some embodiments, the first spacer 138 is a conformal layer formed by a conformal process, such as an atomic layer deposition (ALD) process.

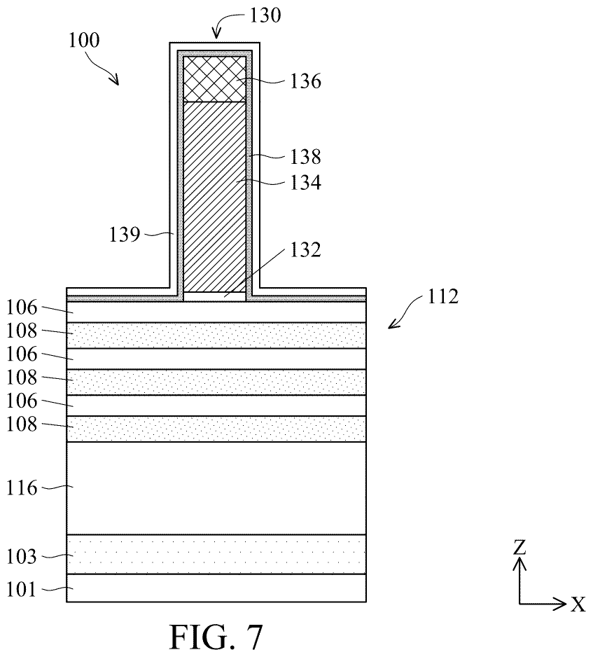

As shown in FIG. 7, a second spacer 139 is deposited on the first spacer 138. The second spacer 139 may include any suitable dielectric material, such as SiOₓ, SiON, SiN, SiCON, or SiCO. The second spacer 139 may have a thickness ranging from about 0.5 nm to about 5 nm. The second spacer 139 may be formed by any suitable process. In some embodiments, the second spacer 139 is deposited by CVD, PECVD, or electron cyclotron resonance CVD (ECR-CVD). In some embodiments, the second spacer 139 is not present, and the semiconductor device structure 100 includes a single spacer 138, as shown in FIG. 15.

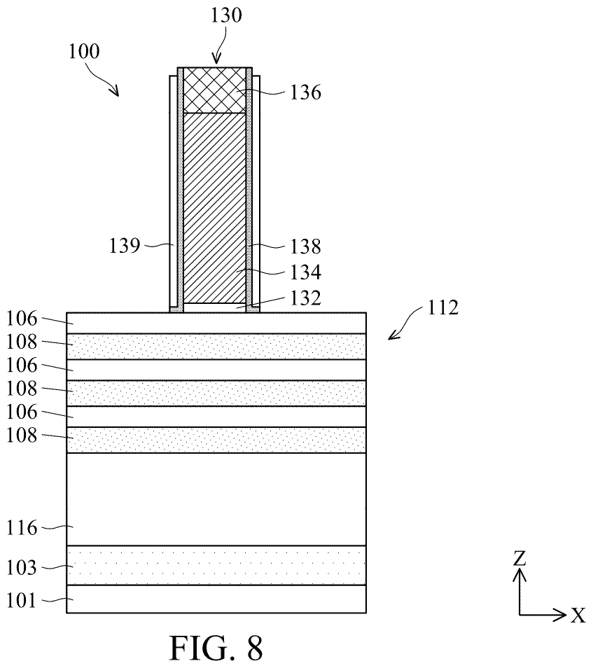

As shown in FIG. 8, horizontal portions of the first and second spacers 138, 139 are removed. In some embodiments, the horizontal portions of the first and second spacers 138, 139 are removed by an anisotropic etch process. The anisotropic etch process may be a selective etch process that does not substantially affect the mask layer 136, the stack of semiconductor layers 104, and the isolation regions 120.

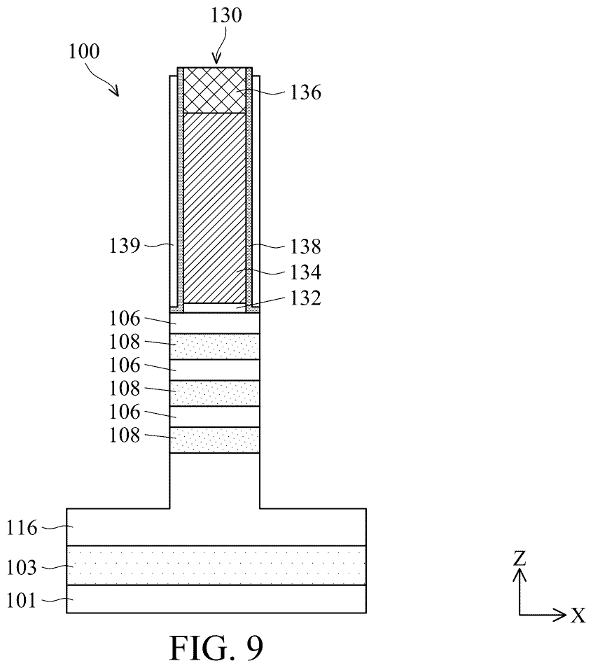

As shown in FIG. 9, the portions of the fin structures 112 not covered by the sacrificial gate structure 130 and the first and second spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant. The substrate portions 116 are exposed on opposite sides of the sacrificial gate structure 130, as shown in FIG. 9. In some embodiments, the spacer 138 located on side surfaces of the recessed portions of the fin structures 112 is also recessed, as shown in FIG. 15.

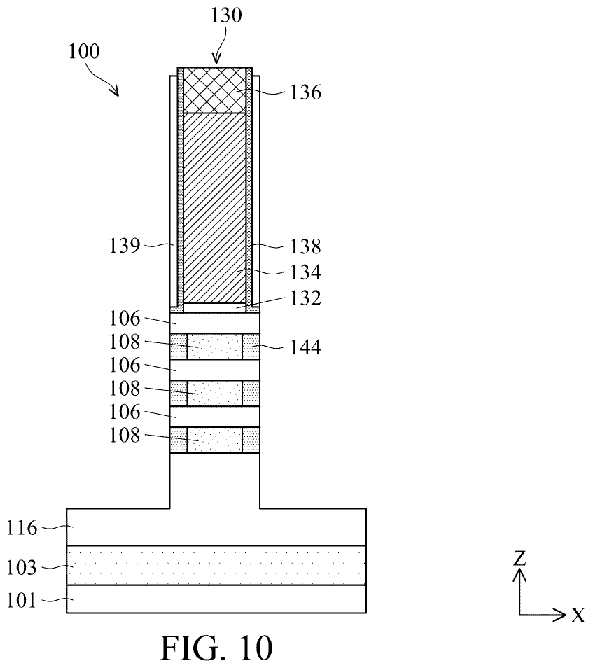

As shown in FIG. 10, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, SiO, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

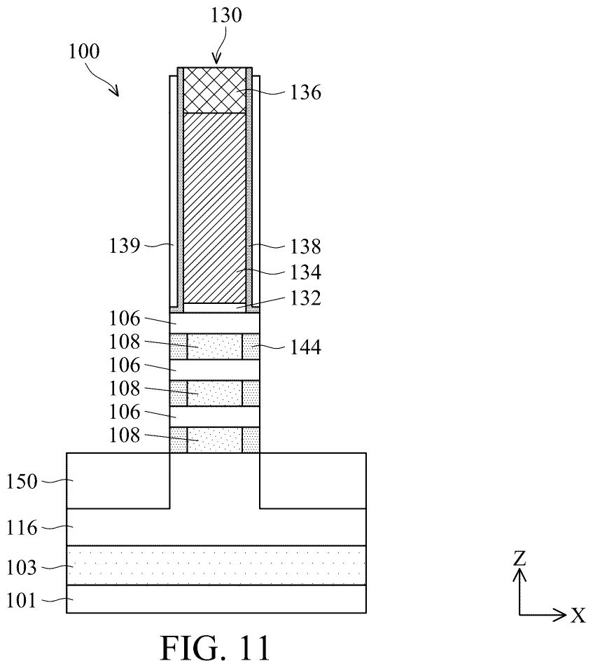

As shown in FIG. 11, a layer, such as a layer including a first semiconductor material 150 formed on the exposed substrate portions 116. In some embodiments, the first semiconductor material 150 includes undoped silicon or undoped SiGe. In some embodiments, the term undoped may include materials being unintentionally doped. For example, the layer may contain dopant diffused from other regions, such as the substrate portion 116. The first semiconductor material 150 may be first formed on semiconductor surfaces, such as on the exposed substrate portions 116 and on the first semiconductor layers 106, by epitaxy. A subsequent etch process is performed to remove the portions of the first semiconductor material 150 formed on the first semiconductor layers 106. The first semiconductor material 150 formed on the exposed substrate portions 116 may form a concave top surface as the result of the etch process. In some embodiments, the first semiconductor material 150 has a thickness ranging from about 5 nm to about 50 nm along the Z direction.

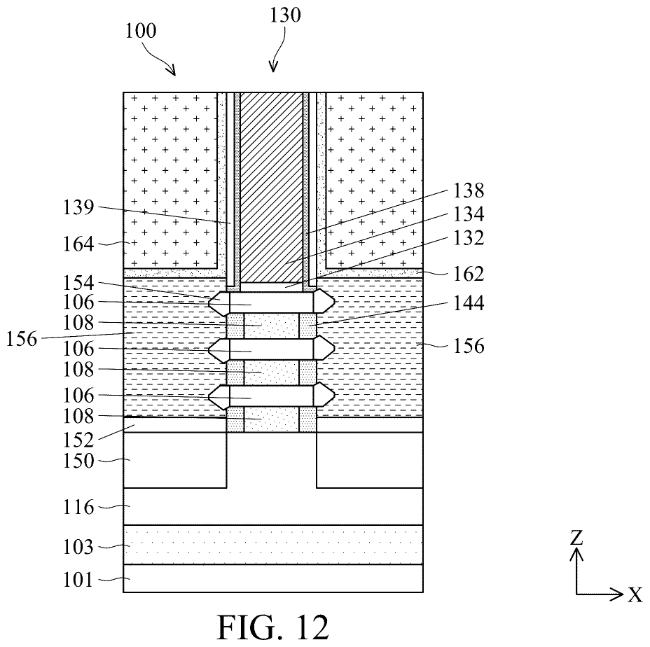

Next, as shown in FIG. 12, a layer 152 is formed on the first semiconductor material 150. The layer 152 may be formed by first forming a continuous layer on the exposed surfaces of the semiconductor device structure 100, followed by one or more etch processes to remove portions of the continuous layer other than the layer 152. A mask layer (not shown), such as a bottom anti-reflective coating (BARC) layer, may be used to assist with the removal of the portions of the continuous layer. The layer 152 may include any suitable material, such as SiC, LaO, AlO, AlON, ZrO, HfO, SiN, Si, ZnO, ZrN, ZrAlO, TiO, TaO, YO, TaCN, ZrSi, SiOCN, SiOC, SiCN, HfSi, LaO, or SiO. In some embodiments, the layer 152 includes a dielectric material and may function as an isolation layer to prevent current leakage from the subsequently formed S/D regions to the substrate portion 116 located under the second semiconductor layer 108. In some embodiments, the layer 152 includes a material different from the material of the insulating material 118 and functions as an etch stop layer during backside processing. In some embodiments, a top surface of the layer 152 may be concave, due to the concave top surface of the semiconductor material 150. In some embodiments, the layer 152 is not present, and a second semiconductor material 154 is formed on the first semiconductor material 150.

Next, the second semiconductor material 154 is formed from the first semiconductor layers 106. The second semiconductor material 154 may be made of one or more layers of Si, SiP, SiC, SiAs, SiSb, and SiCP for n-channel FETs or Si, SiGe, Ge, SiGeB for p-channel FETs. For p-channel FETs, p-type dopants, such as boron (B), may be included in the second semiconductor material 154. For n-channel FETs, n-type dopants, such as phosphorus (P) or arsenic (As), may be included in the second semiconductor material 154. In some embodiments, the dopant concentration of the second semiconductor material 154 may range from about 1×10¹⁹ cm⁻³ to about 2×10²¹ cm⁻³. The second semiconductor material 154 may be formed by an epitaxial growth method using CVD, ALD or MBE. As shown in FIG. 12, in some embodiments, the second semiconductor material 154 is selectively formed on semiconductor materials, such as the first semiconductor layers 106, and is not formed on dielectric materials, such as the layer 152 and the dielectric spacers 144. In some embodiments, the second semiconductor material 154 includes facets, which may correspond to crystalline planes of the material used for the first semiconductor layers 106. In some embodiments, the second semiconductor material 154 includes discrete portions extending from the first semiconductor layers 106 along the X direction, as shown in FIG. 12. In some embodiments, the second semiconductor material 154 is a continuous layer that is also formed on the side surfaces of the dielectric spacers 144. In such embodiments, the second semiconductor material 154 may be also formed on and in contact with the layer 152.

Next, as shown in FIG. 12, a third semiconductor material 156 is formed from the second semiconductor material 154. The third semiconductor material 156 may be formed by an epitaxial growth method using CVD, ALD or MBE. The third semiconductor material 156 may be made of one or more layers of Si, SiP, SiC and SiCP for n-type FETs or Si, SiGe, SiGeB, Ge for p-type FETs. For p-type FETs, p-type dopants, such as boron (B), may be included in the second semiconductor material 154. For n-type FETs, n-type dopants, such as phosphorus (P) or arsenic (As), may be included in the third semiconductor material 156. In some embodiments, the second semiconductor material 154 and the third semiconductor material 156 may include the same semiconductor materials but with different dopant concentrations. The dopant concentration of the third semiconductor material 156 may be substantially greater than the dopant concentration of the second semiconductor material 154. In some embodiments, the dopant concentration of the third semiconductor material 156 may range from about 5×10¹⁹ cm⁻³ to about 4×10²¹ cm⁻³. The third semiconductor material 156 may be epitaxially grown from the second semiconductor material 154. The quality of the third semiconductor material 156 may be improved due to the facets of the second semiconductor material 154.

In some embodiments, a cap layer (not shown) may be formed on the third semiconductor material 156. The cap layer may include a semiconductor material. In some embodiments, the cap layer includes the same material as the third semiconductor material. The cap layer may be epitaxially grown from the third semiconductor material 156.

In some embodiments, the second and third semiconductor materials 154, 156 may be in-situ doped during growth. If the dopant concentrations of the second and third semiconductor materials 154, 156 are greater than the above-mentioned respective ranges, the quality of the second and third semiconductor material 154, 156 may be negatively affected.

The second semiconductor material 154 and the third semiconductor material 156 together may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. In some embodiments, p-type S/D regions and n-type S/D regions may be formed separately using one or more mask layers. In some embodiments, the second semiconductor material 154 and the third semiconductor material 156 are crystalline semiconductor materials.

Next, as shown in FIG. 12, a contact etch stop layer (CESL) 162 is conformally formed on the exposed surfaces of the semiconductor device structure 100. The CESL 162 covers the second spacer 139, the isolation regions 120, and the third semiconductor material 156 (or the cap layer if present). The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 12. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 12.

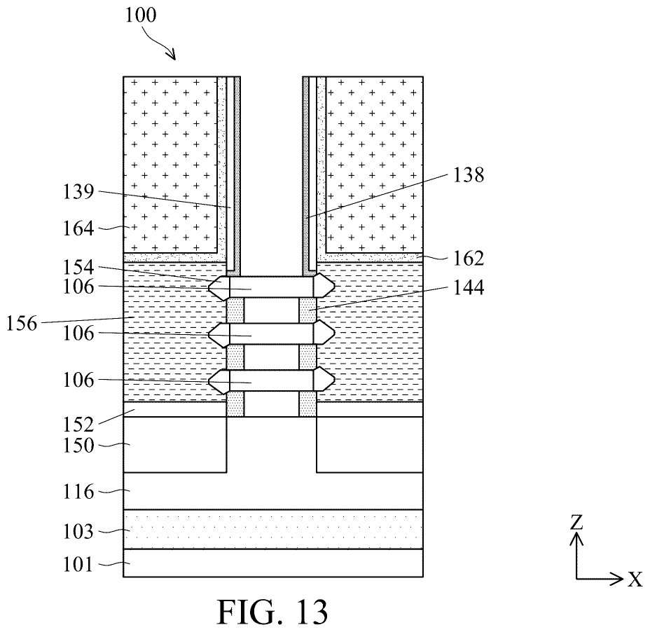

Next, as shown in FIG. 13, the sacrificial gate structure 130 and the second semiconductor layers 108 are removed. The removal of the sacrificial gate structure 130 and the semiconductor layers 108 forms an opening between the first spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, wet etchant such as a tetramethylammonium hydroxide (TMAH) solution can be used to selectively remove the sacrificial gate electrode layer 134 but not the first spacers 138, the ILD layer 164, and the CESL 162.

The second semiconductor layers 108 may be removed using a wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

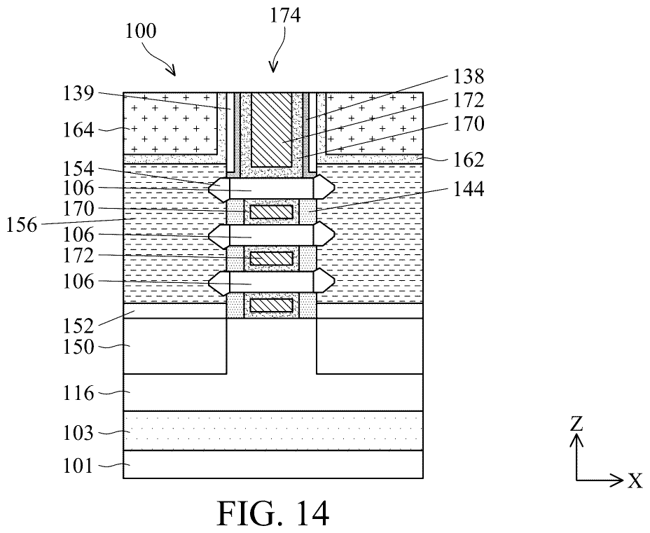

As shown in FIG. 14, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the ILD layer 164. The gate dielectric layer 170 and the gate electrode layer 172 formed over the ILD layer 164 are then removed by using, for example, CMP, until the top surfaces of the dielectric layers 163 are exposed.

It is understood that the semiconductor device structure 100 may undergo further processes, such as cut metal gate (CMG) process and/or continuous poly on diffusion edge (CPODE) process. The CMG process separates the gate electrode layer 172 into multiple segments that can be individually controlled. The CPODE process forms isolation between devices.

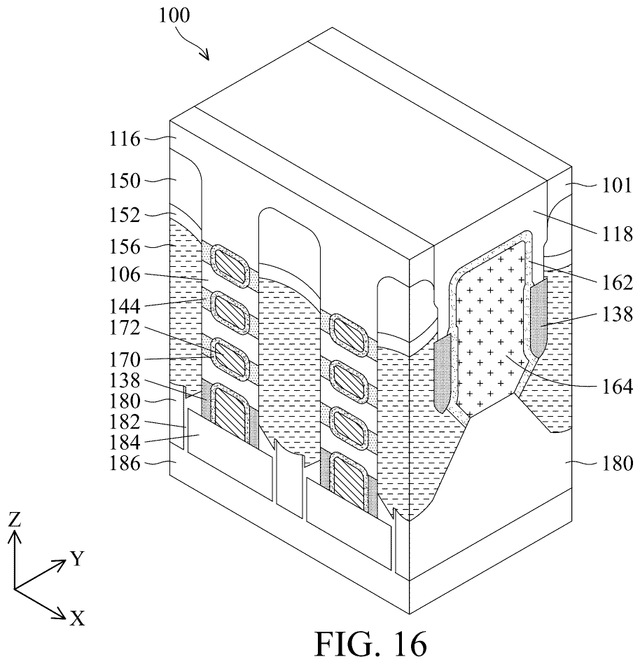

FIGS. 15 and 16 are perspective views of various stages of manufacturing the semiconductor device structure 100, in accordance with some embodiments. FIG. 15 illustrates the perspective view of the semiconductor device structure 100 shown in FIG. 14. The second semiconductor material 154 is omitted for clarity. In some embodiments, the semiconductor device structure 100 includes a single spacer 138, and the insulating material 118 extends through the layer 103, as shown in FIG. 15.

Next, as shown in FIG. 16, another ILD layer 184 is deposited on the semiconductor device structure 100, and conductive features 180 are formed in the ILD layer 184. The ILD layer 184 may include the same material as the ILD layer 164. The conductive features 180 may include any suitable electrically conductive material, such as a metal. In some embodiments, the conductive features 180 includes W, Ru, Co, Cu, or Mo. The conductive feature 180 may be formed by any suitable process, such as PVD or ECP. In some embodiments, optional liners 182 may be formed on side surfaces of the conductive features 180, as shown in FIG. 16. The liners 182 may include TaN or TiN. An etch stop layer 186 is deposited on the conductive features 180 and the ILD layer 184. Silicide layers (not shown) may be formed between the conductive features 180 and the third semiconductor material 156 to electrically connect the conductive features 180 and the corresponding semiconductor material 156. An interconnect structure (not shown) may be formed over the etch stop layer 186. Then, the semiconductor device structure 100 is flipped over for backside processing, as shown in FIG. 16. The portion of the substrate 101 located over the layer 103 is removed by any suitable process, such as a grinding process. In some embodiments, the layer 103 functions as a stop layer during the grinding process. Then, the layer 103 is removed to expose the insulating material 118 and the remaining portion of the substrate 101, as shown in FIG. 16. The layer 103 may be removed by any suitable process.

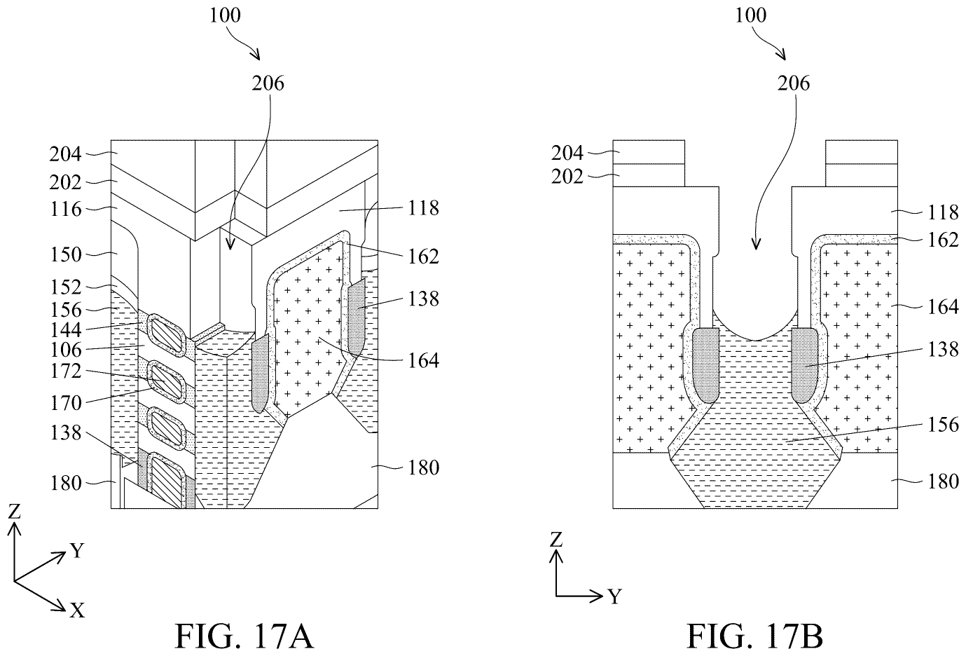

FIGS. 17A, 18A, 19A, 20A, 21A, and 22A are perspective views of various stages of manufacturing the semiconductor device structure 100, in accordance with some embodiments. FIGS. 17B, 18B, 19B, 20B, 21B, and 22B are corresponding cross-sectional side views of the semiconductor device structure 100 of FIGS. 17A, 18A, 19A, 20A, 21A, and 22A, respectively, in accordance with some embodiments. As shown in FIGS. 17A and 17B, a first mask layer 202 and a second mask layer 204 are formed on the substrate 101 and the insulating material 118. The first mask layer 202 may include a nitride, such as silicon nitride, and the second mask layer 204 may include an oxide, such as silicon oxide. An opening 206 is formed in the mask layers 202, 204 to expose the substrate 101 (FIG. 16). In some embodiments, the opening 206 in the mask layers 202, 204 has a larger dimension along the Y direction than the dimension of the substrate 101 along the Y direction. Next, an etching process is performed to remove the exposed portion of the substrate 101. The etching process may be a dry etching process, a wet etching process, or a combination thereof. The etching process may remove the semiconductor material of the exposed portion of the substrate 101, while the dielectric material of the insulating material 118 is not substantially affected. In some embodiments, the etching process also removes the semiconductor material 150 located under the exposed portion of the substrate 101, as shown in FIGS. 17A and 17B, because the semiconductor material 150 is also made of a semiconductor material. In some embodiments, the layer 152 includes a dielectric material and functions as an etch stop layer during the etching process. In some embodiments, after the etching process to remove the exposed portion of the substrate 101 and the semiconductor material 150 located thereunder, another etching process is performed to remove the exposed layer 152. In some embodiments, the layer 152 includes a material different from that of the insulating material 118. The etching process removes the layer 152 but not the insulating material 118, as shown in FIGS. 17A and 17B.

In some embodiments, the surface of the third semiconductor material 156 (or the top surface of the second semiconductor material 154) in contact with the layer 152 may have a flat or a convex profile, as shown in FIG. 16. In some embodiments, the etching process that removes the layer 152 also removes a portion of the third semiconductor material 156 (or the second semiconductor material 154, if the second semiconductor material 154 are formed on and in contact with the layer 152 as described in FIG. 12), and the top surface of the third semiconductor material 156 (or the second semiconductor material 154) has a concave profile after the etching process. In some embodiments, the etching process that removes the layer 152 does not affect the third semiconductor material 156 (or the second semiconductor material 154), and the top surface of the third semiconductor material 156 (or the second semiconductor material 154) remains being flat or convex.

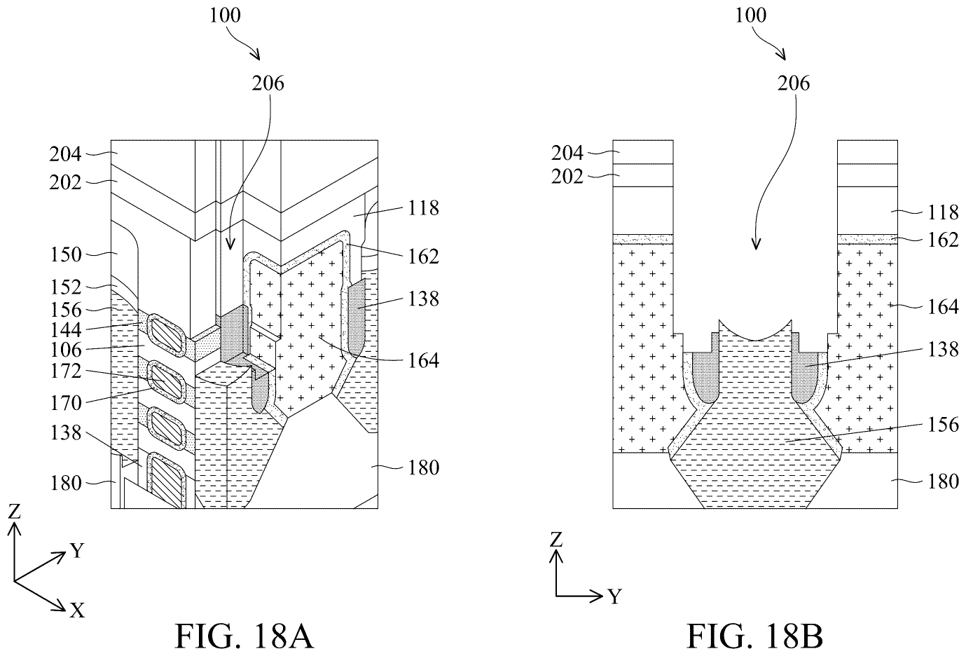

As shown in FIGS. 18A and 18B, the opening 206 is widened. In some embodiments, the widening of the opening 206 is achieved by performing an implantation process followed by an etching process. The implantation process may include implanting an element into the portions of the insulating material 118, the CESL 162, the ILD layer 164, and the spacer 138. In some embodiments, the implantation process is angled to minimize implanting the element into the third semiconductor material 156. The angle of the implantation process may range from about 0 degrees to about 90 degrees. The element being implanted into the above-mentioned components may be any element that can create a difference in etch selectivity compared to the portions of the insulating material 118, the CESL 162, the ILD layer 164, and the spacer 138 that are not being implanted. In some embodiments, the element is Ar, La, Al, or Xe.

After implanting portions of the insulating material 118, the CESL 162, the ILD layer 164, and the spacer 138 with the element, an etching process, such as a wet etching process, is performed to remove the implanted portions. In some embodiments, the wet etching process may use any suitable etchant, such as a first solution including a mixture of ammonia hydroxide, hydrogen peroxide, and water, a second solution including a mixture of hydrochloric acid, hydrogen peroxide, and water, hydrogen peroxide, deionized water, deionized ozone, or diluted hydrofluoric acid. The etching process does not substantially affect the portions of the insulating material 118, the CESL 162, the ILD layer 164, and the spacer 138 not being implanted. In some embodiments, steps may form on the side surfaces of the ILD layer 164 and/or the spacer 138, as shown in FIG. 18B, as a result of the angled implantation process and the etching process.

In some embodiments, other processes may be performed instead of the implantation and etching process to widen the opening 206. For example, an anisotropic etching process may be performed to remove the exposed portion of the insulating material 118 and the portions of the CESL 162, the ILD layer 164, and the spacer 138 located therebelow. The anisotropic etching process may be a selective etching process that removes the dielectric materials of the portions of the insulating material 118, the CESL 162, the ILD layer 164, and the spacer 138, while the semiconductor material of the third semiconductor material 156 (or the second semiconductor material 154) may not be affected by the anisotropic etching process.

In some embodiments, the widening of the opening 206 also exposes portions of the side surfaces of the third semiconductor material 156 (or the second semiconductor material 154), because the spacer 138 is recessed, as shown in FIG. 18B. In some embodiments, the opening 206 is widened by about 1 nm to about 15 nm.

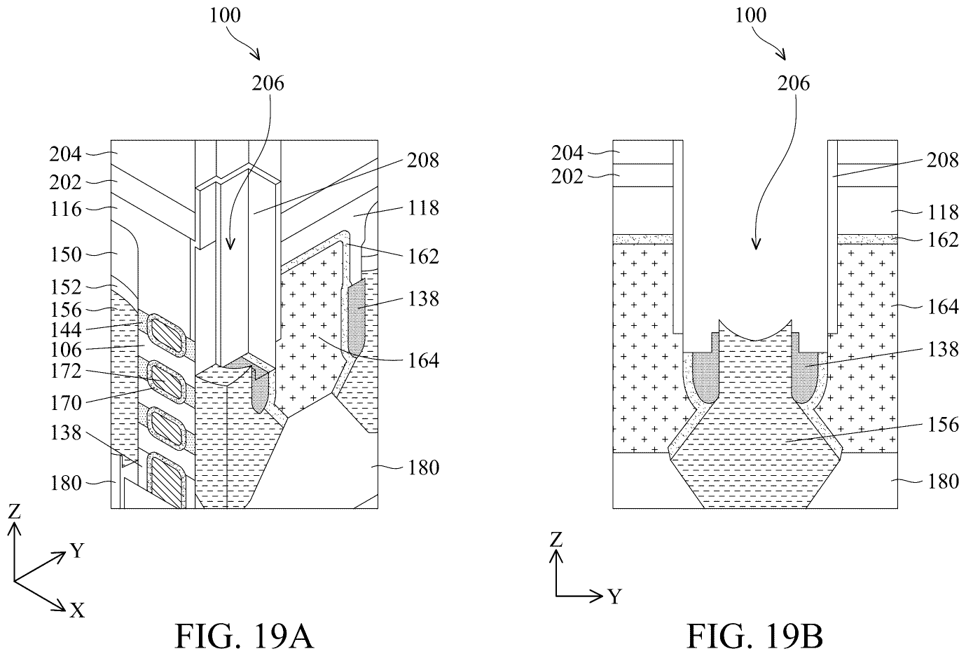

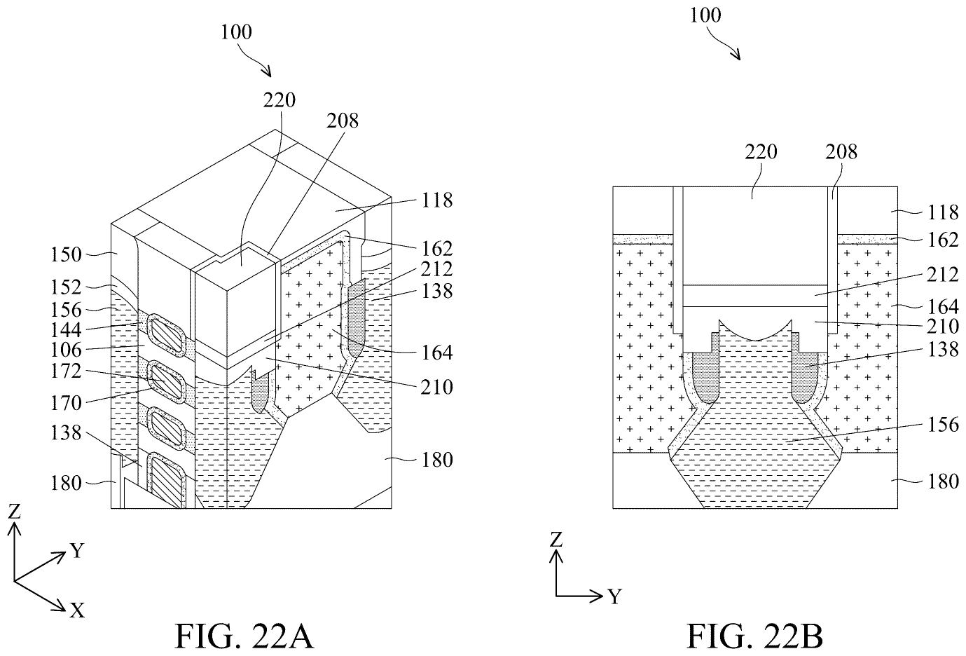

As shown in FIGS. 19A and 19B, a dielectric layer 208 is formed on the sidewall in the opening 206. In some embodiments, the dielectric layer 208 is formed on the side surfaces of the insulating material 118, the CESL 162, and the ILD layer 164, as shown in FIGS. 19A and 19B. The dielectric layer 208 may include any suitable dielectric material. In some embodiments, the dielectric layer 208 includes a nitride, such as SiN. The dielectric layer 208 electrically isolates the substrate portion 116 located over the gate electrode layer 172 and a subsequently formed conductive feature 220 (FIGS. 22A and 22B). In other words, current leakage from the conductive feature 220 to the gate electrode layer 172 is minimized by having the dielectric layer 208. In some embodiments, the dielectric layer 208 is formed by first depositing a blanked layer on the exposed surfaces of the semiconductor device structure 100 followed by removing portions of the blanked layer formed on the horizontal surfaces of the semiconductor device structure 100 by an anisotropic etching process. In some embodiments, a high bias power may be applied during the anisotropic etching process to ensure that at least a portion of the side surface of the third semiconductor material 156 (or the second semiconductor material 154) is exposed, as shown in FIG. 19B.

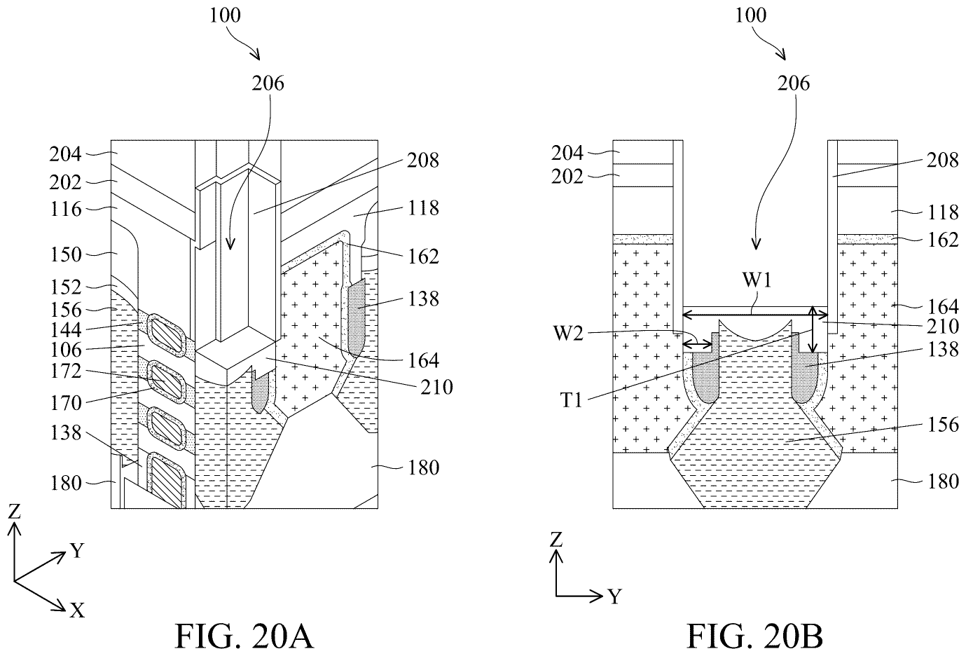

Next, as shown in FIGS. 20A and 20B, a fourth semiconductor material 210 are epitaxially grown from the exposed portions of the third semiconductor material 156 (or the second semiconductor material 154). In some embodiments, the fourth semiconductor material 210 includes the same material as the third semiconductor material 156, but the dopant concentration of the fourth semiconductor material 210 is greater than the dopant concentration of the third semiconductor material 156. For example, the dopant concentration of the fourth semiconductor material 210 ranges from about 1×10¹⁹ cm⁻³ to about 1×10²² cm⁻³, such as from about 6×10¹⁹ cm⁻³ to about 1×10²² cm⁻³. As described above, if a semiconductor material is doped in-situ, and the dopant concentrations of the semiconductor material is greater than 5×10¹⁹ cm⁻³ to about 4×10²¹ cm−³, the quality of the semiconductor material may be negatively affected. Thus, in some embodiments, the fourth semiconductor material 210 has a first dopant concentration, such as from about 5×10¹⁹ cm⁻³ to about 4×10²¹ cm⁻³, after the epitaxial process, and a subsequent doping process may be performed to increase the first dopant concentration to a second dopant concentration, such as from about 6×10¹⁹ cm⁻³ to about 1×10²² cm⁻³. In some embodiments, the epitaxial process to form the fourth semiconductor material 210 is a low temperature epitaxial process having a processing temperature ranging from about 300 degrees Celsius to about 470 degrees Celsius. The low temperature process ensures that metal of the conductive features 180 and the conductive features in the interconnect structure are not negatively affected.

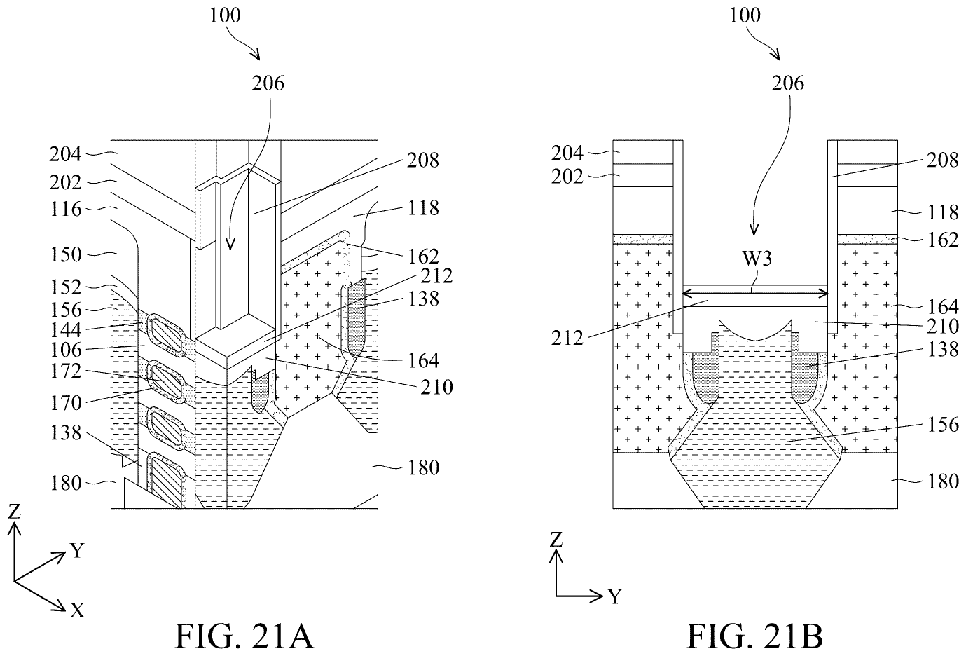

In some embodiments, as shown in FIG. 20B, the fourth semiconductor material 210 is grown from the top surface and side surfaces of the third semiconductor material 156 (or the second semiconductor material 154). Thus, in some embodiments, the fourth semiconductor material 210 has an “M” cross-sectional shape. For example, the fourth semiconductor material 210 includes a longitudinal portion (horizontal portion) and two edge portions (vertical portions) extending from the longitudinal portion. In some embodiments, the longitudinal portion has a bottom surface having a concave profile, as a result of the concave profile of the top surface of the third semiconductor material 156. The top surface of the fourth semiconductor material 210 may be flat, concave, or convex, which may be controlled by the epitaxial process to grow the fourth semiconductor material 210. In some embodiments, the shape of the top surface of the fourth semiconductor material 210 is the same as the shape of the top surface of the third semiconductor material 156 (or the second semiconductor material 154). In some embodiments, the shape of the top surface of the fourth semiconductor material 210 is different from the shape of the top surface of the third semiconductor material 156 (or the second semiconductor material 154). The top surface of the fourth semiconductor material 210 has a width W1 ranging from about 10 nm to about 80 nm. The portion of the fourth semiconductor material 210 located adjacent the third semiconductor material 156 (or the second semiconductor material 154) has a bottom surface having a width W2 ranging from about 1 nm to about 10 nm. The thickness T1 of the fourth semiconductor material 210 may range from about 1 nm to about 10 nm. The portions of the fourth semiconductor material 210 formed adjacent the third semiconductor material 156 (or the second semiconductor material 154) lead to an enlarged top surface of the fourth semiconductor material 210. As a result, the dimensions of a silicide layer 212 (FIGS. 21A and 21B) formed on the top surface of the fourth semiconductor material 210 are also enlarged, leading to reduced electrical contact resistance. Furthermore, the high dopant concentration of the fourth semiconductor material 210 also reduces electrical resistance.

As shown in FIGS. 21A and 21B, the silicide layer 212 is formed on the top surface of the fourth semiconductor material 210. The silicide layer 212 may include any suitable material, such as TiSi, MoSi, RuSi, WSi, TiN, RhSi, NbSi, IrSi, YSi, SbSi, ScSi, or ZrSi. The silicide layer 212 may be formed by any suitable process. In some embodiments, a metal layer (not shown) is first formed on the exposed surfaces of the semiconductor device structure 100, and the metal layer reacts with the fourth semiconductor material 210 to form the silicide layer 212. Next, a nitridation process may be performed to convert the remaining metal layer to a metal nitride layer, and a selective etching process is performed to remove the metal nitride layer without substantially affect the silicide layer 212 and the dielectric layer 208. As described above, the dimensions of the silicide layer 212, such as the width W3 of the silicide layer 212 along the Y direction, is enlarged as a result of having the fourth semiconductor material 210. In some embodiments, the width W3 is substantially the same as the width W1. The thickness of the silicide layer 212 along the Z direction may range from about 1 nm to about 10 nm. In some embodiments, the silicide layer 212 has a depth along the X direction ranging from about 5 nm to about 40 nm.

As shown in FIGS. 22A and 22B, a conductive feature 220 is formed in the opening 206 to fill the opening 206. The conductive feature 220 may include the same material as the conductive feature 180. Portions of the conductive feature 220 formed over the insulating material 118 may be removed by a planarization process, such as a CMP process. The conductive feature 220 may have a thickness along the Z direction ranging from about 5 nm to about 40 nm, a width along the Y direction ranging from about 10 nm to about 80 nm, and a depth along the X direction ranging from about 5 nm to about 40 nm. As described above, the silicide layer 212 is enlarged as a result of having the fourth semiconductor material 210, which leads to enlarged landing area for the conductive feature 220. As a result, contact resistance is reduced, such as a reduction by about 45 percent.

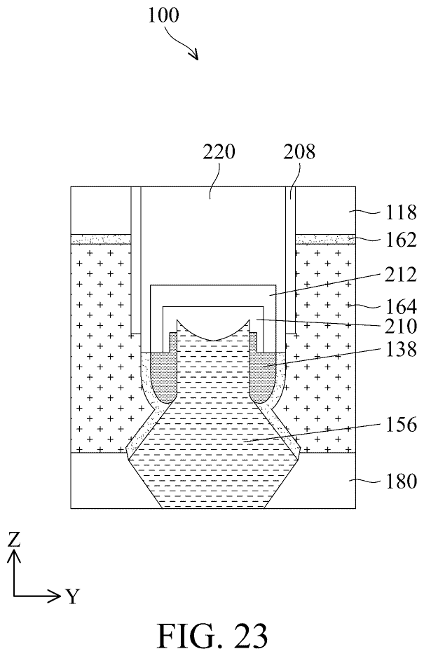

In some embodiments, the width W1 of the fourth semiconductor material 210 is about the same as the critical dimension of the opening 206 (dimension of the opening 206 along the Y direction), as shown in FIG. 20B. In such embodiments, the silicide layer 212 is a flat layer, as shown in FIG. 21B. In some embodiments, the width W1 of the fourth semiconductor material 210 is substantially less than the critical dimension of the opening 206, and the silicide layer 212 wraps around three sides of the fourth semiconductor material 210, as shown in FIG. 23. For example, the silicide layer 212 covers three surfaces of the fourth semiconductor material 210. In some embodiments, the conductive feature 220 wraps around three sides of the silicide layer 212, as shown in FIG. 23. For example, the conductive feature 220 covers three surfaces of the silicide layer 212. In some embodiments, the top surface of the third semiconductor material 156 (or the second semiconductor material 154) in contact with the fourth semiconductor material 210 may be flat, concave, or convex. The top surface of the fourth semiconductor material 210 in contact with the silicide layer 212 may be flat, concave, or convex.

Embodiments of the present disclosure provide a semiconductor device structure and methods of forming the same. In some embodiments, the semiconductor device structure 100 includes a source/drain region including a first semiconductor material (the third semiconductor material 156 or the second semiconductor material 154) and a second semiconductor material (the fourth semiconductor material 210) disposed on the first semiconductor material. The second semiconductor material covers portions of the side surfaces of the first semiconductor material. A silicide layer 212 is disposed on the second semiconductor material. Some embodiments may achieve advantages. For example, the second semiconductor material enlarges the dimensions of the silicide layer 212, which creates a larger landing area for a conductive feature 220. As a result, contact resistance is reduced.

An embodiment is a semiconductor device structure. The structure includes an interlayer dielectric (ILD) layer, a first semiconductor material disposed adjacent the ILD layer, and a second semiconductor material disposed over the first semiconductor material. The second semiconductor material covers a first portion of a side surface of the first semiconductor material. The structure further includes a silicide layer disposed on the second semiconductor material and a first conductive feature disposed on the silicide layer.

Another embodiment is a semiconductor device structure. The structure includes an interlayer dielectric (ILD) layer, a first semiconductor material disposed adjacent the ILD layer, a semiconductor layer disposed adjacent the first semiconductor material, a second semiconductor material disposed between the semiconductor layer and the first semiconductor material, and a third semiconductor material disposed over the first semiconductor material. The third semiconductor material wraps at least two sides of the first semiconductor material. The structure further includes a silicide layer disposed on the third semiconductor material and a conductive feature disposed on the silicide layer.

A further embodiment is a method. The method includes forming a first semiconductor material over a substrate, forming an interlayer dielectric (ILD) layer over the first semiconductor material, flipping over the substrate, forming an opening in the substrate to expose the first semiconductor material, widening the opening, and forming a second semiconductor material on the first semiconductor material. The second semiconductor material covers a portion of a side surface of the first semiconductor material. The method further includes depositing a silicide layer on the second semiconductor material and depositing a conductive feature on the silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an interlayer dielectric (ILD) layer;
a first semiconductor material disposed adjacent the ILD layer;
a second semiconductor material disposed over the first semiconductor material, wherein the second semiconductor material covers a first portion of a side surface of the first semiconductor material;
a silicide layer disposed on the second semiconductor material; and
a first conductive feature disposed on the silicide layer.

2. The semiconductor device structure of claim 1, further comprising a spacer covering a second portion of the side surface of the first semiconductor material.

3. The semiconductor device structure of claim 2, further comprising a dielectric layer in contact with the first conductive feature, the silicide layer, and the second semiconductor material.

4. The semiconductor device structure of claim 3, further comprising a contact etch stop layer in contact with the spacer and the first semiconductor material.

5. The semiconductor device structure of claim 4, further comprising a second conductive feature disposed in the ILD layer.

6. The semiconductor device structure of claim 5, further comprising an insulating material disposed over the ILD layer, wherein the first conductive feature is disposed in the insulating material.

7. The semiconductor device structure of claim 1, wherein the first semiconductor material has a first dopant concentration, and the second semiconductor material has a second dopant concentration greater than the first dopant concentration.

8. The semiconductor device structure of claim 1, wherein the silicide layer wraps around at least two sides of the second semiconductor material, and a top surface of the first semiconductor material has a concave profile.

9. A semiconductor device structure, comprising:
an interlayer dielectric (ILD) layer;
a first semiconductor material disposed adjacent the ILD layer;
a semiconductor layer disposed adjacent the first semiconductor material;
a second semiconductor material disposed between the semiconductor layer and the first semiconductor material;
a third semiconductor material disposed over the first semiconductor material, wherein the third semiconductor material wraps at least two sides of the first semiconductor material;
a silicide layer disposed on the third semiconductor material; and
a conductive feature disposed on the silicide layer.

10. The semiconductor device structure of claim 9, wherein the first semiconductor material has a first dopant concentration, the second semiconductor material has a second dopant concentration, and the third semiconductor material has a third dopant concentration.

11. The semiconductor device structure of claim 10, wherein the third dopant concentration is greater than the first dopant concentration, and the first dopant concentration is greater than the second dopant concentration.

12. The semiconductor device structure of claim 9, wherein a top surface of the first semiconductor material is concave or convex.

13. The semiconductor device structure of claim 9, wherein a top surface of the third semiconductor material is concave or convex.

14. The semiconductor device structure of claim 9, wherein the silicide layer wraps around at least two sides of the third semiconductor material.

15. The semiconductor device structure of claim 14, wherein the conductive feature wraps around at least two sides of the silicide layer.

16. A method, comprising:
forming a first semiconductor material over a substrate;
forming an interlayer dielectric (ILD) layer over the first semiconductor material;
flipping over the substrate;
forming an opening in the substrate to expose the first semiconductor material;
widening the opening;
forming a second semiconductor material on the first semiconductor material, wherein the second semiconductor material covers a portion of a side surface of the first semiconductor material;
depositing a silicide layer on the second semiconductor material; and
depositing a conductive feature on the silicide layer.

17. The method of claim 16, wherein the widening of the opening comprises performing an implantation process and an etching process.

18. The method of claim 17, wherein the implantation process comprises implanting an element into a portion of an insulating material, a portion of the ILD layer, a portion of a contact etch stop layer, and a portion of a spacer.

19. The method of claim 18, wherein the element comprises Ar, La, Al, or Xe.

20. The method of claim 18, wherein the etching process comprises a wet etching process to remove the implanted portions of the insulating material, the ILD layer, the contact etch stop layer, and the spacer.
